(19) United States
(12) Patent Application Publication
(10) Pub. No.: US 2011/0052795 A1
(43) Pub. Date: Mar. 3, 2011

(54) THIN FILM DEPOSITION APPARATUS AND METHOD OF MANUFACTURING ORGANIC LIGHT-EMITTING DISPLAY DEVICE BY USING THE SAME

(75) Inventors: Young-Mook CHOI, Yongin-City (KR); Chang-Mog Jo, Yongin-City (KR); Hee-Cheol Kang, Yongin-City (KR); Young-Sup Choi, Yongin-City (KR); Yun-Ml Lee, Yongin-City (KR)

(73) Assignee: Samsung Mobile Display Co., Ltd., Yongin-city (KR)

(21) Appl. No.: 12/873,556

(22) Filed: Sep. 1, 2010

(30) Foreign Application Priority Data
Sep. 1, 2009 (KR) 10-2009-0081978
Feb. 17, 2010 (KR) 10-2010-0014274

(51) Int. Cl. C23C 16/04; C23C 16/44; C23C 16/458

(52) U.S. Cl. 427/69; 118/721; 118/719

(57) ABSTRACT

A thin film deposition apparatus includes an electrostatic chuck that fixes a substrate on which a deposition material is to be deposited; a blocking member disposed at a side of the substrate fixed on the electrostatic chuck and covering at least a portion of the substrate; and a deposition unit including a chamber and a thin film deposition assembly disposed in the chamber and to deposit a thin film on the substrate fixed on the electrostatic chuck.

### CROSS-REFERENCE TO RELATED APPLICATIONS

This application claims the benefit of Korean Application Nos. 10-2009-0081978, filed on Sep. 1, 2009 and 10-2010-0014274, filed on Feb. 17, 2010, in the Korean Intellectual Property Office, the disclosures of which are incorporated herein by reference.

### BACKGROUND OF THE INVENTION

1. Field of the Invention

Aspects of the present invention relate to a thin film deposition apparatus and a method of manufacturing an organic light-emitting display device by using the same, and more particularly, to a thin film deposition apparatus that can be simply applied to manufacture large-sized display devices on a mass scale and that improves manufacturing yield, and a method of manufacturing an organic light-emitting display device by using the thin film deposition apparatus.

2. Description of the Related Art

Organic light-emitting display devices have a larger viewing angle, better contrast characteristics, and a faster response rate than other display devices, and thus have drawn attention as a next-generation display device.

Organic light-emitting display devices generally have a stacked structure including an anode, a cathode, and an emission layer interposed between the anode and the cathode. The devices display images in color when holes and electrons, injected respectively from the anode and the cathode, recombine in the emission layer such that light is emitted. However, it is difficult to achieve high light-emission efficiency with such a structure, and thus intermediate layers, including an electron injection layer, an electron transport layer, a hole transport layer, a hole injection layer, or the like, may be additionally interposed between the emission layer and one or both of the electrodes.

Also, it is very difficult in practice to form fine patterns in organic thin films such as the emission layer and the intermediate layers, and red, green, and blue light-emission efficiency varies according to characteristics of the organic thin films. For these reasons, it is not easy to form an organic thin film pattern on a large substrate, such as a mother glass having a size of 5 G or more, by using a conventional thin film deposition apparatus, and thus it is difficult to manufacture large organic light-emitting display devices having satisfactory driving voltage, current density, brightness, color purity, light-emission efficiency, life-span characteristics. Thus, there is a desire for improvement in this regard.

An organic light-emitting display device includes intermediate layers, including an emission layer disposed between a first electrode and a second electrode that are arranged opposite to each other. The interlayer and the first and second electrodes may be formed using a variety of methods, one of which is a deposition method. When an organic light-emitting display device is manufactured by using the deposition method, a fine metal mask (FMM) having the same pattern as a thin film to be formed is disposed to closely contact a substrate, and a thin film material is deposited over the FMM in order to form the thin film having the desired pattern.

### SUMMARY OF THE INVENTION

Aspects of the present invention provide a thin film deposition apparatus that may be easily manufactured, that may be simply applied to manufacture large-sized display devices on a mass scale and that allows high-definition patterning, and a method of manufacturing an organic light-emitting display device by using the thin film deposition apparatus.

According to an aspect of the present invention, there is provided a thin film deposition apparatus including: an electrostatic chuck that fixes a substrate on which a deposition material is to be deposited; a blocking member that is disposed at a side of the substrate fixed on the electrostatic chuck and that covers at least a portion of the substrate; and a deposition unit comprising a chamber and at least one thin film deposition assembly disposed in the chamber to deposit a thin film on the substrate fixed on the electrostatic chuck.

According to a non-limiting aspect, the blocking member may cover an area of the substrate in which no layers are to be formed.

According to a non-limiting aspect, the blocking member may cover a border portion of the substrate.

According to a non-limiting aspect, at least a portion of the substrate may be interposed between the electrostatic chuck and the blocking member.

According to a non-limiting aspect, the blocking member may include a frame including an open area and a blocking sheet attached to a side of the frame and covering at least a portion of the substrate.

According to a non-limiting aspect, a magnet may be disposed at the electrostatic chuck and a magnetic substance may be disposed at the blocking member, or the magnet substance may be disposed at the electrostatic chuck and the magnet may be disposed at the blocking member so that the blocking member is fixed on the electrostatic chuck due to a magnetic force between the magnet and the magnetic substance.

According to a non-limiting aspect, the thin film deposition apparatus may further include: a loading unit that fixes the substrate on which a deposition material is to be deposited onto the electrostatic chuck; an unloading unit that separates the substrate on which deposition has been performed from the electrostatic chuck; a first circulation unit that sequentially moves the electrostatic chuck on which the substrate is fixed to the loading unit, from the loading unit to the deposition unit, and from the deposition unit to the unloading unit; and a second circulation unit that returns the electrostatic chuck, after the electrostatic chuck has been separated from the substrate by the unloading unit, to the loading unit, wherein the first circulation unit is disposed to pass through the chamber while traversing the deposition unit.

According to a non-limiting aspect, a plurality of thin film deposition assemblies may be disposed in the chamber.

According to a non-limiting aspect, the chamber may include a first chamber and a second chamber, wherein each of the first chamber and the second chamber has at least one thin film deposition assembly disposed therein, and wherein the first chamber and the second chamber may be connected to each other.

According to a non-limiting aspect, the thin film deposition assembly may include: a deposition source that discharges a deposition material; a deposition source nozzle unit disposed at a side of the deposition source and including a plurality of deposition source nozzles arranged in a first direction; a patterning slit sheet disposed opposite to and spaced apart from the deposition source nozzle unit and including a plurality of patterning slits arranged in the first direction; and a barrier wall assembly disposed between the deposition source nozzle unit and the patterning slit sheet, and including a plurality of barrier walls in the first direction that partition a space between the deposition source nozzle unit and the patterning slit sheet into a plurality of sub-deposition spaces, and wherein the thin film deposition assembly is spaced apart from the substrate, and the thin film deposition assembly and the substrate are movable relative to each other.

According to a non-limiting aspect, the patterning slit sheet of the thin film deposition assembly may be smaller than the substrate.

According to a non-limiting aspect, each of the plurality of barrier walls may extend in a second direction substantially perpendicular to the first direction.

According to a non-limiting aspect, the plurality of barrier walls may be arranged at equal intervals.

According to a non-limiting aspect, the barrier wall assembly may include a first barrier wall assembly including a plurality of first barrier walls, and a second barrier wall assembly including a plurality of second barrier walls.

According to a non-limiting aspect, each of the first barrier walls and each of the second barrier walls may extend in a second direction substantially perpendicular to the first direction.

According to a non-limiting aspect, the first barrier walls may be arranged to respectively correspond to the second barrier walls.

According to a non-limiting aspect, each pair of the corresponding first and second barrier walls may be arranged on substantially the same plane.

According to a non-limiting aspect, the deposition source and the barrier wall assembly may be spaced apart from each other.

According to a non-limiting aspect, the barrier wall assembly may be spaced apart from the patterning slit sheet.

According to a non-limiting aspect, the chamber includes a plurality of thin film deposition assemblies and wherein deposition materials contained in the deposition sources of the plurality of thin film deposition assemblies may be continuously deposited on the substrate while the substrate and the thin film deposition assembly are moved relative to each other.

According to a non-limiting aspect, the thin film deposition assembly and the substrate may be movable relative to each other along a plane parallel to a surface of the substrate on which the deposition materials are deposited.

According to a non-limiting aspect, the thin film deposition assembly may include: a deposition source that discharges a deposition material; a deposition source nozzle unit disposed at a side of the deposition source and including a plurality of deposition source nozzles arranged in a first direction; and a patterning slit sheet disposed opposite to the deposition source nozzle unit and including a plurality of patterning slits arranged in a second direction perpendicular to the first direction, and wherein deposition is performed while the substrate and the thin film deposition assembly are moved relative to each other in the first direction, and wherein the deposition source, the deposition source nozzle unit, and the patterning slit sheet are formed integrally with each other.

According to a non-limiting aspect, the deposition source and the deposition source nozzle unit, and the patterning slit sheet may be connected to each other by a connection member.

According to a non-limiting aspect, the connection member may guide movement of the discharged deposition material.

According to a non-limiting aspect, the connection member may seal a space between the deposition source and the deposition source nozzle unit, and the patterning slit sheet.

According to a non-limiting aspect, the thin film deposition assembly may be separated from the substrate by a predetermined distance.

According to a non-limiting aspect, the deposition material discharged from the thin film deposition assembly may be continuously deposited on the substrate while the substrate and the thin film deposition assembly are moved relative to each other in the first direction.

According to a non-limiting aspect, the patterning slit sheet of the thin film deposition assembly may be smaller than the substrate.

According to a non-limiting aspect, the plurality of deposition source nozzles may be tilted at a predetermined angle.

According to a non-limiting aspect, the plurality of deposition source nozzles may include deposition source nozzles arranged in two rows disposed in the first direction, and wherein each of the deposition source nozzles in each of the two rows may be tilted at a predetermined angle toward a corresponding deposition source nozzle of the other of the two rows.

According to a non-limiting aspect, the plurality of deposition source nozzles may include deposition source nozzles arranged in two rows disposed in the first direction, and the deposition source nozzles arranged in a row located at a first side of the patterning slit sheet may be arranged to face a second side of the patterning slit sheet, and the deposition source nozzles arranged in the other row located at the second side of the patterning slit sheet may be arranged to face the first side of the patterning slit sheet.

According to another aspect of the present invention, there is provided a method of manufacturing an organic light-emitting display device, the method including: fixing a substrate on an electrostatic chuck; disposing a blocking member at a side of the substrate fixed on the electrostatic chuck to cover at least a portion of the substrate; and depositing a thin film on the substrate fixed on the electrostatic chuck.

According to a non-limiting aspect, the disposing of the blocking member at a side of the substrate fixed on the electrostatic chuck to cover at least a portion of the substrate may include disposing the blocking member to cover an area of the substrate in which no layers are to be formed.

According to a non-limiting aspect, the disposing of the blocking member at a side of the substrate fixed on the electrostatic chuck to cover at least a portion of the substrate may include disposing the blocking member to cover a border portion of the substrate.

According to a non-limiting aspect, the depositing of the thin film on the substrate fixed on the electrostatic chuck may include: conveying the electrostatic chuck on which the substrate is fixed from a loading location to a chamber by engaging the electrostatic chuck with first circulation unit that passes through the chamber; moving the substrate and a thin film deposition assembly disposed in the chamber relative to each other such that a deposition material discharged from the thin film deposition assembly is deposited on the substrate; engaging the first circulation unit to remove the substrate on which deposition has been performed from the chamber; separating the substrate on which deposition has been performed, from the electrostatic chuck; and engaging the electrostatic chuck separated from the substrate with a second circulation unit installed outside the chamber to return the electrostatic chuck to the loading position.

According to a non-limiting aspect, a plurality of thin film deposition assemblies may be disposed in the chamber, and wherein deposition may be continuously performed on the substrate by using each of the plurality of thin film deposition assemblies.

According to a non-limiting aspect, the chamber may include a first chamber and a second chamber, wherein the first chamber and the second chamber each include a plurality of thin film deposition assemblies, wherein the first chamber and the second chamber are connected to each other, and wherein deposition may be continuously performed while the substrate is moved through the first chamber and the second chamber.

According to a non-limiting aspect, the thin film deposition assembly may include: a deposition source that discharges a deposition material; a deposition source nozzle unit disposed at a side of the deposition source and including a plurality of deposition source nozzles arranged in a first direction; a patterning slit sheet disposed opposite to and spaced apart from the deposition source nozzle unit and including a plurality of patterning slits arranged in the first direction; and a barrier wall assembly disposed between the deposition source nozzle unit and the patterning slit sheet in the first direction, and including a plurality of barrier walls that partition a space between the deposition source nozzle unit and the patterning slit sheet into a plurality of sub-deposition spaces, and wherein the thin film deposition assembly is spaced apart from the substrate, and wherein depositing of the thin film on the substrate is performed while the thin film deposition assembly and the substrate are moved relative to each other.

According to a non-limiting aspect, the thin film deposition assembly may include: a deposition source that discharges a deposition material; a deposition source nozzle unit disposed at a side of the deposition source and including a plurality of deposition source nozzles arranged in a first direction; and a patterning slit sheet disposed opposite to and spaced apart from the deposition source nozzle unit and including a plurality of patterning slits arranged in a second direction perpendicular to the first direction, and wherein depositing of the thin film on the substrate is performed while the substrate and the thin film deposition assembly are moved relative to each other in the first direction, and wherein the deposition source, the deposition source nozzle unit, and the patterning slit sheet are formed integrally with each other.

According to another embodiment of the present invention, a thin film deposition apparatus for use with a substrate having non-deposition regions at peripheral edges of the substrate includes an electrostatic chuck to which the substrate is fixed by electrostatic attraction; a blocking member including a frame and a blocking sheet that is disposed to cover the non-deposition regions at the peripheral edges of the substrate; and a deposition unit comprising a chamber and at least one thin film deposition assembly disposed in the chamber to deposit a thin film on the substrate fixed on the electrostatic chuck.

According to another embodiment of the present invention, a thin film deposition apparatus for use with a substrate having non-deposition regions at peripheral edges of the substrate, the thin film deposition apparatus includes a loading unit that fixes the substrate on which a deposition material is to be deposited onto the electrostatic chuck and that applies a blocking member to the electrostatic chuck, wherein the blocking member includes a frame and a blocking sheet that is disposed to cover the non-deposition regions at the peripheral edges of the substrate; a deposition unit comprising a chamber and at least one thin film deposition assembly disposed in the chamber to deposit a thin film on the substrate fixed on the electrostatic chuck; an unloading unit that removes the blocking member and the substrate on which deposition has been performed from the electrostatic chuck; a first circulation unit that sequentially moves the electrostatic chuck from the loading unit through the chamber of the deposition unit, and from the deposition unit to the unloading unit; and a second circulation unit that returns the electrostatic chuck from which the blocking member and the substrate have been removed by the unloading unit, to the loading unit.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic system configuration diagram of a thin film deposition apparatus according to an embodiment of the present invention;

FIG. 2 is a system configuration diagram of a modified example of the thin film deposition apparatus of FIG. 1;

FIG. 3 is a schematic view of an electrostatic chuck, according to an embodiment of the present invention;

FIG. 4 is a perspective view of a thin film deposition assembly according to an embodiment of the present invention;

FIG. 5 is a schematic side sectional view of the thin film deposition assembly illustrated in FIG. 4, according to an embodiment of the present invention;

FIG. 6 is a schematic plan sectional view of the thin film deposition assembly of FIG. 4, according to an embodiment of the present invention;

FIG. 7 is a partially-cut perspective view of an electrostatic chuck of the thin film deposition apparatus of FIG. 1;

FIG. 8 is a perspective view of a blocking member of the thin film deposition apparatus of FIG. 1;

FIG. 9 is an exploded side sectional view illustrating the relationship between an electrostatic chuck, a blocking member, and a substrate;

FIG. 10 is a combined side sectional view illustrating the relationship between an electrostatic chuck, a blocking member, and a substrate;

FIG. 11 is a perspective view of a modified example of the thin film deposition assembly of FIG. 4;

FIG. 12 is a cross-sectional view of an organic light-emitting display device manufactured by using a thin film deposition assembly, according to an embodiment of the present invention;

FIG. 13 is a perspective view of a thin film deposition assembly according to another embodiment of the present invention;

FIG. 14 is a schematic side sectional view of the thin film deposition assembly illustrated in FIG. 13, according to an embodiment of the present invention;

FIG. 15 is a schematic plan sectional view of the thin film deposition assembly illustrated in FIG. 13, according to an embodiment of the present invention;

FIG. 16 is a schematic perspective view of a thin film deposition assembly according to another embodiment of the present invention;

FIG. 17 is a graph schematically illustrating a distribution pattern of a deposition layer formed on a substrate when a deposition source nozzle is not tilted, in the thin film deposition assembly of FIG. 16, according to an embodiment of the present invention; and

FIG. 18 is a graph schematically illustrating a distribution pattern of a deposition layer formed on a substrate when a deposition source nozzle is tilted, in the thin film deposition assembly of FIG. 16, according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the aspects of the present invention by referring to the figures.

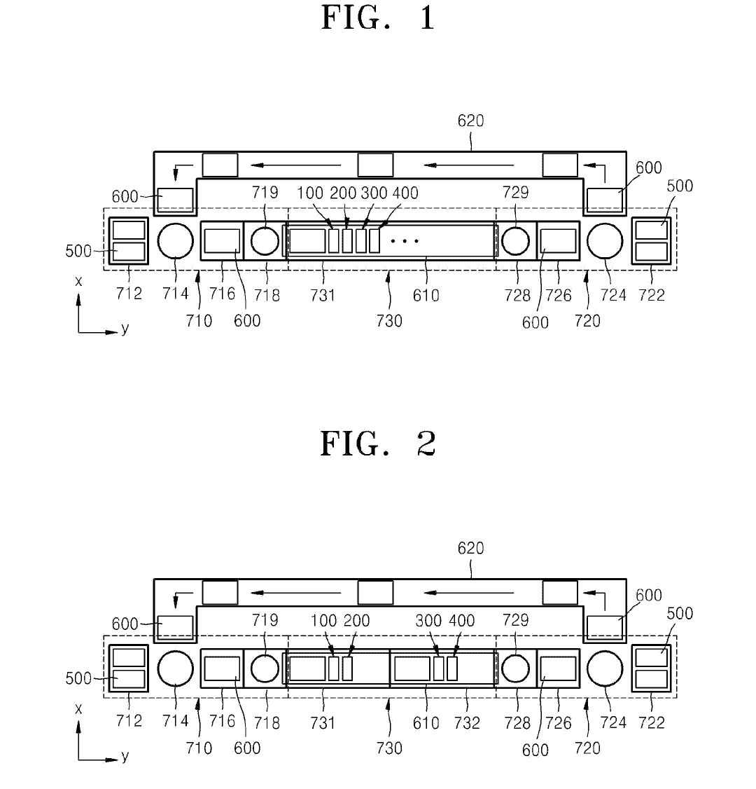

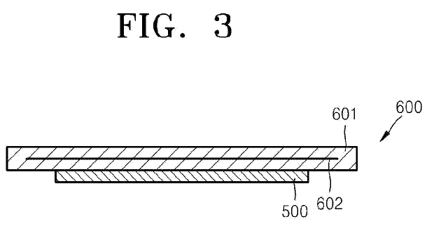

FIG. 1 is a schematic system configuration diagram of a thin film deposition apparatus according to an embodiment of the present invention, FIG. 2 illustrates a modified example of the thin film deposition apparatus of FIG. 1, and FIG. 3 is a schematic view of an electrostatic chuck 600 according to an embodiment of the present invention.

Referring to FIG. 1, the thin film deposition apparatus according to the current embodiment includes a loading unit 710, a deposition unit 730, an unloading unit 720, a first circulation unit 610, and a second circulation unit 620.

The loading unit 710 may include a first rack 712, an introduction robot 714, an introduction chamber 716, and a first inversion chamber 718.

A plurality of substrates 500 on which deposition has not yet been performed are stacked on the first rack 712. The introduction robot 714 picks up the substrates 500 one at a time from the first rack 712, puts each substrates 500 on an electrostatic chuck 600 conveyed from the second circulation unit 620 and then conveys each electrostatic chuck 600, on which a substrates 500 has been put, to the introduction chamber 716.

The first inversion chamber 718 is disposed adjacent to the introduction chamber 716. A first inversion robot 719 located at the first inversion chamber 718 inverts the electrostatic chuck 600 to mount the electrostatic chuck 600 on the first circulation unit 610 of the deposition unit 730.

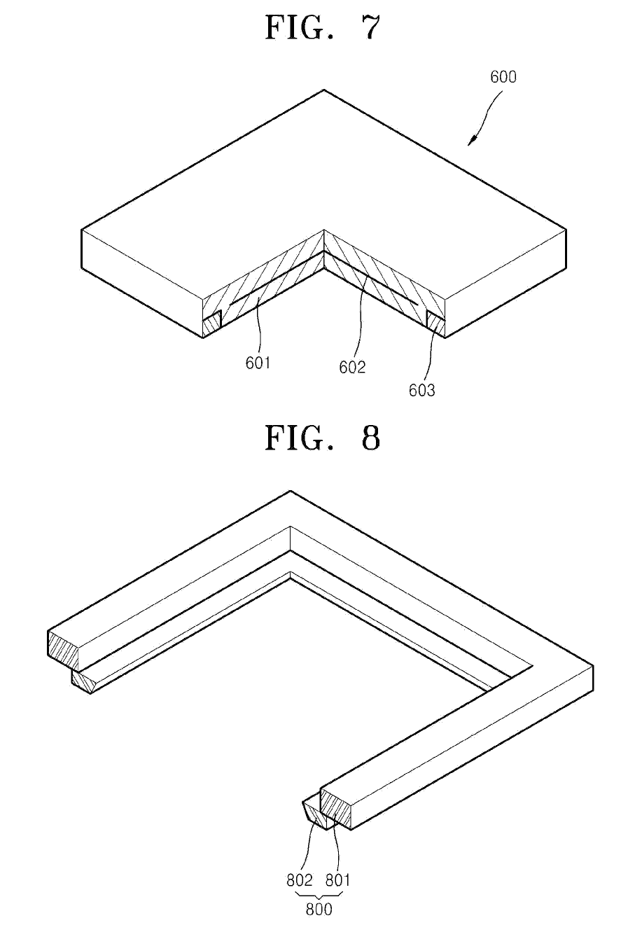

As illustrated in FIG. 3, the electrostatic chuck 600 includes an electrode 602 embedded in a main body 601 of the electrostatic chuck 600 formed of ceramic, wherein the electrode is supplied with power. Such an electrostatic chuck 600 may fix one of the substrates 500 on a surface of the main body 601 when a high voltage is applied to the electrode 602. In this regard, the thin film deposition apparatus according to the current embodiment further includes a blocking member 800 (see FIG. 8) disposed at an edge portion of the substrate 500 fixed on the electrostatic chuck 600. The blocking member prevents an organic material from being deposited onto an area of the substrate 500 on which no layers are to be formed. The relationship of the blocking member 800 and the electrostatic chuck 600 will be described with reference to FIG. 7 and the following drawings later in detail.

Referring to FIG. 1, the introduction robot 714 puts one of the substrates 500 on a top surface of the electrostatic chuck 600. In this state, the electrostatic chuck 600 is conveyed to the introduction chamber 716. As the first inversion robot 719 inverts the electrostatic chuck 600, the substrates 500 are directed downwards in the deposition unit 730. In FIGS. 1 and 2, terms such as “top surface” and “downwards” are with reference to a “top surface” being a surface facing the viewer in FIGS. 1 and 2 and “downwards” being in a direction away from the viewer.

The unloading unit 720 may have an opposite structure to that of the loading unit 710 described above. In other words, a substrate 500 and the electrostatic chuck 600 that have passed through the deposition unit 730 are inverted by a second inversion robot 729 in a second inversion chamber 728 and are conveyed to a carrying-out chamber 726. A carrying-out robot 724 takes the substrate 500 and the electrostatic chuck 600 out of the carrying-out chamber 726 and then separates the substrate 500 from the electrostatic chuck 600 and places the substrate 500 on a second rack 722. The electrostatic chuck 600, separated from the substrate 500, is returned to the loading unit 710 via the second circulation unit 620.

However, aspects of the present invention are not limited to what is described above. The substrates 500 may be fixed on a bottom surface of the electrostatic chuck 600 from when the substrates 500 are initially fixed on the electrostatic chuck 600, and the electrostatic chuck 600 may be conveyed to the deposition unit 730, in which case, the first inversion chamber 718, the first inversion robot 719, the second inversion chamber 728, and the second inversion robot 729 are not necessary.

The deposition unit 730 includes at least one deposition chamber. According to the embodiment of FIG. 1, the deposition unit 730 includes a first chamber 731, and a plurality of thin film deposition assemblies 100, 200, 300, and 400 that are disposed in the first chamber 731. According to the embodiment of FIG. 1, four thin film deposition assemblies including a first thin film deposition assembly 100, a second thin film deposition assembly 200, a third thin film deposition assembly 300, and a fourth thin film deposition assembly 400 are installed in the first chamber 731. However, the number of thin film deposition assemblies to be installed in the first chamber 731 may vary according to desired deposition material and deposition condition. In the schematic system configuration diagram of FIG. 1, the thin deposition assemblies 100, 200, 300 and 400 are positioned such that deposition material from the thin deposition assemblies travels in a direction towards the viewer and is deposited on a substrate 500 on a surface of the electrostatic chuck 600 facing the facing the thin deposition assemblies 100, 200, 300 and 400, but it is to be understood that other configurations are possible. The first chamber 731 is maintained at a degree of vacuum when deposition is performed.

Also, according to another embodiment of FIG. 2, the deposition unit 730 includes the first chamber 731 and a second chamber 732 connected to each other. The first and second thin film deposition assemblies 100 and 200 may be disposed in the first chamber 731, and the third and fourth thin film deposition assemblies 300 and 400 may be disposed in the second chamber 732. Of course, the number of chambers may be increased and the number of thin film deposition assemblies may be varied.

According to the embodiment of FIG. 1, the electrostatic chuck 600 on which one of the substrates 500 is fixed, is moved by the first circulation unit 610 to at least the deposition unit 730 and may be sequentially moved to the loading unit 710, the deposition unit 730, and the unloading unit 720. The electrostatic chuck 600 is separated from the substrate 500 in the unloading unit 720 is returned to the loading unit 710 by the second circulation unit 620.

The first circulation unit 610 is disposed to pass through the first chamber 731 when traversing the deposition unit 730, and the second circulation unit 620 allows the electrostatic chuck 600 to be conveyed back to the loading unit 710.

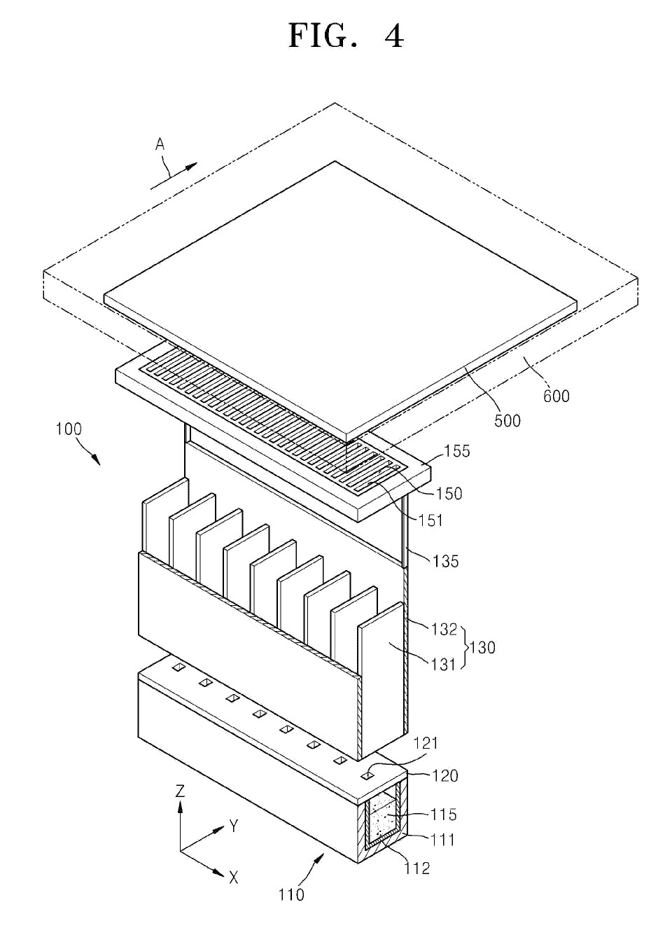

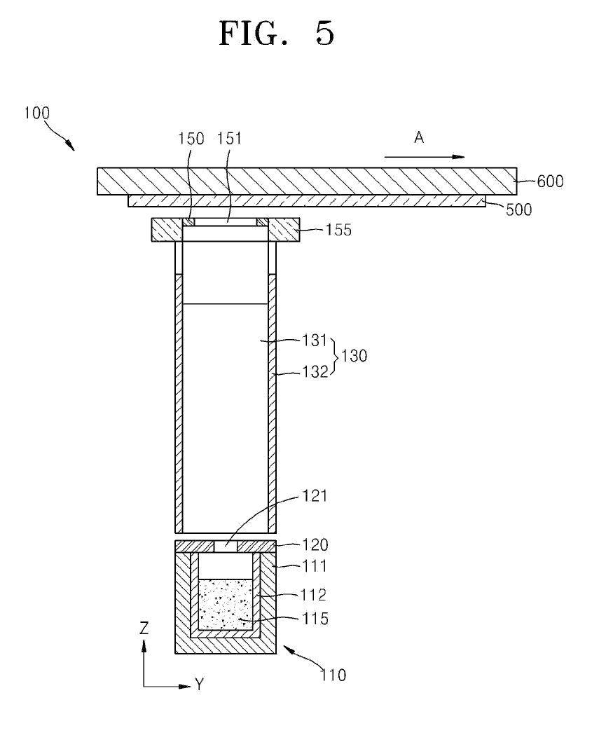

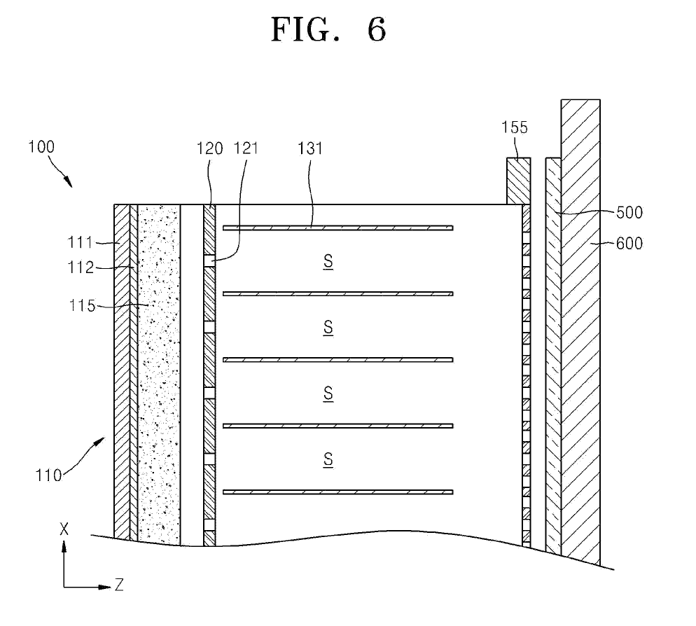

FIG. 4 is a perspective view of a thin film deposition assembly 100 according to an embodiment of the present invention, FIG. 5 is a schematic side sectional view of the thin film deposition assembly 100 illustrated in FIG. 4, according to an embodiment of the present invention, and FIG. 6 is a schematic plan sectional view of the thin film deposition assembly 100 of FIG. 4, according to an embodiment of the present invention.

Referring to FIGS. 4, 5 and 6, the thin film deposition assembly 100 according to the current embodiment includes a deposition source 110, a deposition source nozzle unit 120, a barrier wall assembly 130 including barrier walls 131, and a patterning slit sheet 150.

Although a chamber is not illustrated in FIGS. 4, 5 and 6 for convenience of explanation, all the components of the thin film deposition assembly 100 may be disposed within a chamber that is maintained at an appropriate degree of vacuum, such as the first vacuum chamber 731 or the second vacuum chamber 732. The chamber is maintained at an appropriate vacuum in order to allow a deposition material to move in a substantially straight line through the thin film deposition assembly 100.

In the thin film deposition assembly 100, in order to deposit a deposition material 115 that has been discharged from the deposition source 110 and passed through the deposition source nozzle unit 120 and the patterning slit sheet 150, onto a substrate 500 in a desired pattern, the chamber should be maintained in a high-vacuum state. In addition, the temperatures of barrier walls 131 and the patterning slit sheet 150 may be sufficiently lower than the temperature of the deposition source 110. In this regard, the temperatures of the barrier walls 131 and the patterning slit sheet 150 may be about 100° C. or less, since deposition material 115 that has collided against the barrier walls 131 does not become vaporized again when the temperature of the barrier walls 131 is sufficiently low. In addition, thermal expansion of the patterning slit sheet 150 may be minimized when the temperature of the patterning slit sheet 150 is sufficiently low. The barrier wall assembly 130 faces the deposition source 110, which is at a high temperature. In addition, the temperature of a portion of the barrier wall assembly 130 close to the deposition source 110 may rise by a maximum of about 167° C., and thus a partial-cooling apparatus may be further included if needed.

The substrate 500, which constitutes a target on which a deposition material 115 is to be deposited, is conveyed to a first chamber by the electrostatic chuck 600. The substrate 500 may be a substrate for flat panel displays. A large substrate, such as a mother glass, for manufacturing a plurality of flat panel displays, may be used as the substrate 500. Other substrates may also be employed.

In an embodiment of the present invention, the substrate 500 and the thin film deposition assembly 100 are moved relative to each other. Herein, where it is stated that the substrate and thin film deposition assembly are moved relative to each other, it is to be understood that such statement encompasses an embodiment in which only the substrate is moved and the thin film deposition assembly remains stationary, an embodiment in which only the thin film deposition assembly is moved and the substrate remains stationary and an embodiment in which both the thin film deposition assembly and the substrate are moved. For example, the substrate 500 may be moved in a direction of an arrow A, relative to the thin film deposition assembly 100.

In detail, in a conventional deposition method using a fine metal mask (FMM), the size of the FMM is typically greater than or equal to the size of a substrate. Thus, the size of the FMM should be increased when performing deposition on a larger substrate. However, it is difficult to manufacture a large FMM and to extend an FMM to be accurately aligned with a pattern.

In order to overcome this problem, in the thin film deposition assembly 100 according to the current embodiment, deposition may be performed while the thin film deposition assembly 100 and the substrate 500 are moved relative to each other. In other words, deposition may be continuously performed while the substrate 500, which is disposed such as to face the thin film deposition assembly 100, is moved in a Y-axis direction. That is, deposition is performed in a scanning manner while the substrate 500 is moved in a direction of arrow A in FIG. 4. Although the substrate 500 is illustrated as being moved in the Y-axis direction in a chamber (not shown) when deposition is performed, aspects of the present invention are not limited thereto. Deposition may be performed while the thin film deposition assembly 100 is moved in the Y-axis direction, while the substrate 500 is held in a fixed position. For example, the transporting of the electrostatic chuck 600 having the substrate 500 fixed thereon by the first transporting unit 610 may be paused while deposition is performed.

Thus, in the thin film deposition assembly 100 according to the current embodiment, the patterning slit sheet 150 may be significantly smaller than an FMM used in a conventional deposition method. In other words, in the thin film deposition assembly 100 of the thin film deposition apparatus according to the current embodiment of the present invention, deposition is continuously performed, i.e., in a scanning manner while the substrate 500 is moved in the Y-axis direction. Thus, a length of the patterning slit sheet 150 in the Y-axis direction may be significantly less than a length of the substrate 500 in the Y-axis direction. A width of the patterning slit sheet 150 in the X-axis direction and a width of the substrate 500 in the X-axis direction may be substantially equal to each other. However, even when the width of the patterning slit sheet 150 in the X-axis direction is less than the width of the substrate 500 in the X-axis direction, deposition may be performed on the entire substrate 500 in a scanning manner while the substrate 500 and the thin film deposition assembly 100 are moved relative each other.

As described above, since the patterning slit sheet 150 may be formed to be significantly smaller than an FMM used in a conventional deposition method, it is relatively easy to manufacture the patterning slit sheet 150 used in aspects of the present invention. In other words, using the patterning slit sheet 150, which is smaller than an FMM used in a conventional deposition method, is more convenient in all processes, including etching and subsequent other processes, such as precise extension, welding, moving, and cleaning processes, compared to the conventional deposition method using the larger FMM. This is more advantageous for manufacturing a relatively large display device.

In order to perform deposition while the thin film deposition assembly 100 are the substrate 500 are moved relative to each other as described above, the thin film deposition assembly 100 and the substrate 500 may be separated from each other by a predetermined distance. This will be described later in detail.

The deposition source 110 that contains and heats the deposition material 115 is disposed in an opposite side of the chamber to the side in which the substrate 500 is disposed.

The deposition source 110 includes a crucible 112 and a cooling block 111. The crucible 111 holds the deposition material 115. The cooling block 111 surrounds the crucible 112. The cooling block 111 prevents radiation of heat from the crucible 112 to external areas, such as, for example, the first chamber 731. The cooling block 111 may include a heater (not shown) that heats the crucible 112.

The deposition source nozzle unit 120 is disposed at a side of the deposition source 110 facing the substrate 500. The deposition source nozzle unit 120 includes a plurality of deposition source nozzles 121 arranged at equal intervals in the X-axis direction. The deposition material 115 that is vaporized in the deposition source 110 passes through the deposition source nozzles 121 of the deposition source nozzle unit 120 towards the substrate 500, which constitutes a target on which the deposition material 115 is to be deposited.

The barrier wall assembly 130 is disposed at a side of the deposition source nozzle unit 120. The barrier wall assembly 130 includes a plurality of barrier walls 131, and a barrier wall frame 132 that constitutes an outer wall of the barrier walls 131. The plurality of barrier walls 131 may be arranged parallel to each other at equal intervals in X-axis direction. In addition, each of the barrier walls 131 may be arranged parallel to an YZ plane in FIG. 4, and may have a rectangular shape. The plurality of barrier walls 131, arranged as described above, partition the space between the deposition source nozzle unit 120 and the patterning slit sheet 150 into a plurality of sub-deposition spaces S (see FIG. 6). In the thin film deposition assembly 100 according to the current embodiment, the deposition space is divided by the barrier walls 131 into the sub-deposition spaces S that respectively correspond to the deposition source nozzles 121 through which the deposition material 115 is discharged, as illustrated in FIG. 6.

The barrier walls 131 may be respectively disposed between adjacent deposition source nozzles 121. In other words, each of the deposition source nozzles 121 may be disposed between two adjacent barrier walls 131. The deposition source nozzles 121 may be respectively located at the midpoint between two adjacent barrier walls 131. However, aspects of the present invention are not limited thereto.

As described above, since the barrier walls 131 partition the space between the deposition source nozzle unit 120 and the patterning slit sheet 150 into the plurality of sub-deposition spaces S, the deposition material 115 discharged through each of the deposition source nozzles 121 is not mixed with the deposition material 115 discharged through the other deposition source nozzles 121, and passes through patterning slits 151 so as to be deposited on the substrate 500. Thus, the barrier walls 131 guide the deposition material 115, which is discharged through the deposition source nozzles 121, to move straight, not to flow in the Z-axis direction.

As described above, the deposition material 115 is forced to move in a straight manner the presence of the barrier walls 131, so that a smaller shadow zone may be formed on the substrate 500 compared to a case where no barrier walls are installed. Thus, the thin film deposition assembly 100 and the substrate 500 can be separated from each other by a predetermined distance. This will be described later in detail.

The barrier wall frame 132, which forms sides of the barrier walls 131, maintains the positions of the barrier walls 131, and guides the deposition material 115, which is discharged through the deposition source nozzles 121, not to flow beyond the boundaries of the barrier wall assembly 130 in the Y-axis direction.

The deposition source nozzle unit 120 and the barrier wall assembly 130 may be separated from each other by a predetermined distance. This separation may prevent the heat radiated from the deposition source 110 from being conducted to the barrier wall assembly 130. However, aspects of the present invention are not limited thereto. In particular, an appropriate heat insulator (not shown) may be further disposed between the deposition source nozzle unit 120 and the barrier wall assembly 130. In this case, the deposition source nozzle unit 120 and the barrier wall assembly 130 may be bound together with the heat insulator therebetween.

In addition, the barrier wall assembly 130 may be constructed to be detachable from the thin film deposition assembly 100. In the thin film deposition assembly 100 of the thin film deposition apparatus according to the current embodiment of the present invention, the deposition space is enclosed by using the barrier wall assembly 130, so that the deposition material 115 that is not deposited on the substrate 500 is mostly deposited within the barrier wall assembly 130. Thus, since the barrier wall assembly 130 is constructed to be detachable from the thin film deposition assembly 100, when a large amount of the deposition material 115 is present on the barrier wall assembly 130 after a long deposition process, the barrier wall assembly 130 may be detached from the thin film deposition assembly 100 and then placed in a separate deposition material recycling apparatus in order to recover the deposition material 115. Due to the structure of the thin film deposition assembly 100, a reuse rate of the deposition material 115 is increased, so that the deposition efficiency is improved, and the manufacturing costs are reduced.

The patterning slit sheet 150 and a frame 155 in which the patterning slit sheet 150 is bound are disposed between the deposition source 110 and the substrate 500. The frame 155 may be formed in a lattice shape, similar to a window frame. The patterning slit sheet 150 is bound inside the frame 155. The patterning slit sheet 150 includes a plurality of patterning slits 151 arranged in the X-axis direction. The patterning slits 151 extend as openings in the Y-axis direction. The deposition material 115 that has been vaporized in the deposition source 110 and passed through the deposition source nozzles 121 passes through the patterning slits 151 towards the substrate 500 that is a deposition target.

The patterning slit sheet 150 may be formed of a metal thin film. The patterning slit sheet 150 is fixed to the frame 150 such that a tensile force is exerted thereon. The patterning slits 151 may be formed by etching the patterning slit sheet 150 into a stripe pattern.

In the thin film deposition assembly 100 according to the current embodiment of the present invention, the total number of patterning slits 151 may be greater than the total number of deposition source nozzles 121. In addition, there may be a greater number of patterning slits 151 than deposition source nozzles 121 disposed between two adjacent barrier walls 131. The number of patterning slits 151 may be equal to the number of deposition patterns to be formed on the substrate 500.

In addition, the barrier wall assembly 130 and the patterning slit sheet 150 may be disposed to be spaced apart from each other by a predetermined distance. Alternatively, the barrier wall assembly 130 and the patterning slit sheet 150 may be connected by a connection member 135. The temperature of the barrier wall assembly 130 may increase to 100° C. or higher due to exposure to the deposition source 110, which has a high temperature. Thus, in order to prevent the heat of the barrier wall assembly 130 from being conducted to the patterning slit sheet 150, the barrier wall assembly 130 and the patterning slit sheet 150 may be spaced apart from each other by a predetermined distance.

As described above, the thin film deposition assembly 100 according to the current embodiment performs deposition while being moved relative to the substrate 500. In order for the thin film deposition assembly 100 to be moved relative to the substrate 500, the patterning slit sheet 150 is separated from the substrate 500 by a predetermined distance. In addition, in order to prevent the formation of a relatively large shadow zone on the substrate 500 when the patterning slit sheet 150 and the substrate 500 are separated from each other, the barrier walls 131 are arranged between the deposition source nozzle unit 120 and the patterning slit sheet 150 to force the deposition material 115 to move in a straight direction. Thus, the size of the shadow zone formed on the substrate 500 is sharply reduced.

In particular, in a conventional deposition method using an FMM, deposition is performed with the FMM in close contact with a substrate in order to prevent formation of a shadow zone on the substrate. However, when the FMM is used in close contact with the substrate, the contact may cause defects, such as scratches on patterns formed on the substrate. In addition, in the conventional deposition method, the size of the mask should be the same as the size of the substrate since the mask cannot be moved relative to the substrate. Thus, the size of the mask should be increased as display devices become larger. However, it is not easy to manufacture such a large mask.

In order to overcome this problem, in the thin film deposition assembly 100 according to the current embodiment, the patterning slit sheet 150 is disposed to be separated from the substrate 500 that is a deposition target by a predetermined distance. Shadow zones on the substrate 500 are minimized by installing the barrier walls 131.

As described above, when the patterning slit sheet 150 is manufactured to be smaller than the substrate 500, the pattern slit sheet 150 may be moved relative to the substrate 500 during deposition. Thus, it is no longer necessary to manufacture a large FMM used in the conventional deposition method. In addition, since the substrate 500 and the patterning slit sheet 150 are separated from each other, defects caused due to contact between the substrate and the patterning slit sheet 150 may be prevented. In addition, since it is unnecessary to contact the substrate 500 with the patterning slit sheet 150 during a deposition process, the manufacturing speed may be improved.

According to aspects of the present invention, thin film deposition assemblies 200, 300 and 400 may have the same structure as the thin film deposition assembly 100 described above. Moreover, It is to be understood that the thin film deposition assemblies 100, 200, 300 and 400 may vary from what is described above.

Hereinafter, the electrostatic chuck 600 and a blocking member 800 of the thin film deposition assembly 100 according to an embodiment of the present invention will be described in detail.

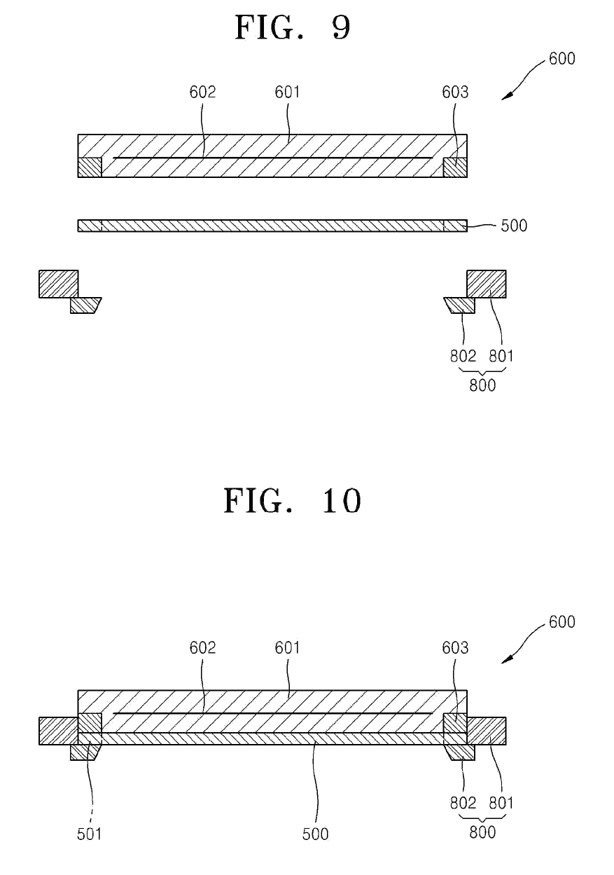

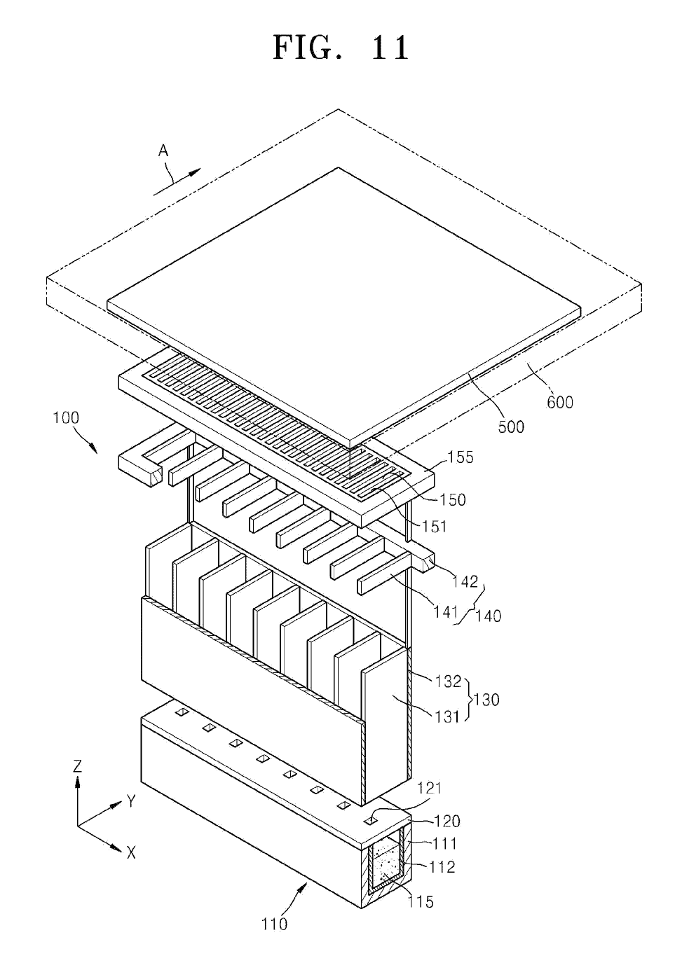

FIG. 7 is a partially-cut perspective view of the electrostatic chuck 600 of the thin film deposition apparatus of FIG. 1, FIG. 8 is a perspective view of a blocking member 800 of the thin film deposition apparatus of FIG. 1, FIG. 9 is an exploded side sectional view illustrating the relationship between the electrostatic chuck 600, the blocking member 800, and the substrate 500, and FIG. 10 is a combined side sectional view illustrating the relationship between the electrostatic chuck 600, the blocking member 800, and the substrate 500.

Referring to FIGS. 7 through 10, the thin film deposition apparatus of FIG. 1 further includes a blocking member 800 disposed at an edge portion of the substrate 500 fixed on the electrostatic chuck 600, thereby preventing an organic material from being deposited in an area of the substrate 500 in which no layers are to be formed.

In detail, anode or cathode patterns are formed in a border portion of the substrate 500, and an area for product inspection or an area to be utilized as a terminal when a product is manufactured, is present. When a layer is formed of an organic material in the area, an anode or a cathode cannot perform its role. Thus, the border portion of the substrate 500 should be an area in which no layers are formed of an organic material or the like. However, as described above, in the thin film deposition apparatus of FIG. 1, deposition is performed in a scanning manner while the substrate 500 is moved relative to the thin film deposition assembly 100. Thus, it is not easy to prevent the organic material from being deposited in the area of the substrate 500 in which no layers are to be formed.

In order to prevent the organic material from being deposited in the area of the substrate 500 in which no layers are to be formed, in the thin film deposition apparatus of FIG. 1, a separate blocking member is disposed at the border portion of the substrate 500.

Referring to FIG. 7, the electrostatic chuck 600 includes an electrode 602 embedded in a main body 601 of the electrostatic chuck 600 formed of ceramic, wherein the electrode 602 is supplied with power. As a high voltage is applied to the electrode 602, the substrate 500 is attached to a surface of the main body 601. A magnet 603 may be further disposed at a border portion of a side of the main body 601 on which the substrate 500 is disposed. Due to the magnet 603, the blocking member 800 that will be described later is magnetically attached to the electrostatic chuck 600 and is moved together with the electrostatic chuck 600.

Referring to FIG. 8, the blocking member 800 includes a frame 801 and a blocking sheet 802. The frame 801 is formed in the form of a window frame including an open center area. The blocking sheet 802 including an open area is attached to a bottom surface of the frame 801. The blocking sheet 802 is formed to correspond to an area of the substrate 500 in which no layers should be formed of an organic material. The area of the substrate 500 in which no layers are to be formed, is covered by the blocking sheet 802 so that the organic material may be prevented from being deposited in the area of the substrate 500 in which no layers are to be formed.

In this regard, in order to bond the blocking member 800 to the electrostatic chuck 600, the blocking sheet 802 may include a magnetic substance. In detail, the blocking member 800 may be bonded to the electrostatic chuck 600 due to a magnetic force between the magnet 603 of the electrostatic chuck 600 and the blocking sheet 802 of the blocking member 800. Alternatively, the magnet 603 may be disposed on the blocking member 800, and the electrostatic chuck 600 may include the magnetic substance. Alternatively, a magnetic member may be disposed on both the electrostatic chuck 600 and the blocking member 800. In this regard, the magnet 603 may be a permanent magnet, an electromagnet or the like. The magnetic substance may be any material that is magnetically attracted to and attachable to the magnet 603.

Referring to FIGS. 9 and 10, as a high voltage is applied to the electrode 602 of the electrostatic chuck 600, the substrate 500 is fixed on the surface of the main body 601 of the electrostatic chuck 600. Then, the blocking member 800 is bonded to a bottom surface of the substrate 500 fixed on the electrostatic chuck 600. (Here, the term “bottom surface” refers to the surface opposite to the surface that is fixed to the electrostatic chuck.) In detail, due to a magnetic force between the magnet 603 of the electrostatic chuck 600 and the blocking sheet 802 of the blocking member 800, the blocking member 800 is attached to the electrostatic chuck 600. In this regard, the blocking sheet 802 of the blocking member 800 is disposed to cover an area 501 of the substrate 500 in which no layers are to be formed. The area 501 of the substrate 500 in which no layers are to be formed is covered by the blocking sheet 802. Thus, the organic material may be prevented from being deposited in the area 501 of the substrate 500 in which no layers are to be formed, conveniently without a separate structure such as a shutter.

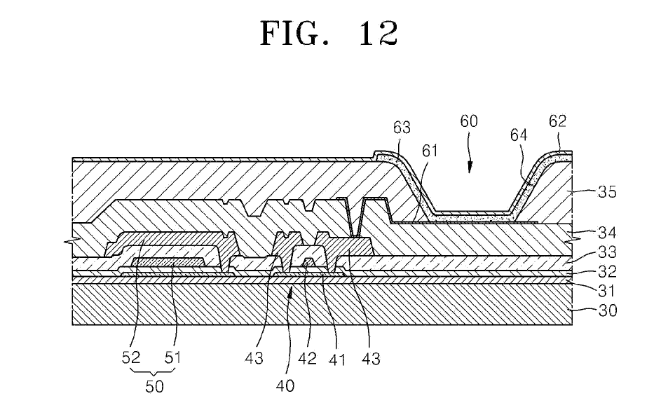

FIG. 11 is a schematic perspective view of a modified example of the thin film deposition assembly 100 of FIG. 4.

Referring to FIG. 11, the thin film deposition assembly 100 according to the current embodiment includes a deposition source 110, a deposition source nozzle unit 120, a first barrier wall assembly 130, a second barrier wall assembly 140, and a patterning slit sheet 150.

Although a chamber is not illustrated in FIG. 11 for convenience of explanation, all the components of the thin film deposition assembly 100 may be disposed within a chamber that is maintained at an appropriate degree of vacuum. The chamber is maintained at an appropriate vacuum in order to allow a deposition material to move in a substantially straight line through the thin film deposition assembly 100.

The substrate 500, which constitutes a target on which a deposition material 115 is to be deposited, is disposed in the chamber. The deposition source 115 that contains and heats the deposition material 115 is disposed in an opposite side of the chamber to the side in which the substrate 500 is disposed.

Detailed structures of the deposition source 110 and the patterning slit sheet 150 are the same as those of FIG. 4 and thus, detailed descriptions thereof will not be repeated here. The first barrier wall assembly 130 is the same the barrier wall assembly 130 of FIG. 4 and thus, a detailed description thereof will not be repeated here.

The second barrier wall assembly 140 is disposed at a side of the first barrier wall assembly 130. The second barrier wall assembly 140 includes a plurality of second barrier walls 141 and a second barrier wall frame 141 that constitutes an outer wall of the second barrier walls 142.

The plurality of second barrier walls 141 may be arranged parallel to each other at equal intervals in the X-axis direction. In addition, each of the second barrier walls 141 may be formed to extend in the YZ plane in FIG. 11, i.e., perpendicular to the X-axis direction.

The plurality of first barrier walls 131 and second barrier walls 141 arranged as described above partition the space between the deposition source nozzle unit 120 and the patterning slit sheet 150. The deposition space is divided by the first barrier walls 131 and the second barrier walls 141 into sub-deposition spaces that respectively correspond to the deposition source nozzles 121 through which the deposition material 115 is discharged.

The second barrier walls 141 may be disposed to correspond to the first barrier walls 131. The second barrier walls 141 may be respectively disposed to be parallel to and to be on the same plane as the first barrier walls 131. Each pair of the corresponding first and second barrier walls 131 and 141 may be located on the same plane. Although the first barrier walls 131 and the second barrier walls 141 are respectively illustrated as having the same thickness in the Y-axis direction, aspects of the present invention are not limited thereto. The second barrier walls 141, which may be accurately aligned with the patterning slit sheet 151, may be formed to be relatively thin, whereas the first barrier walls 131, which do not need to be precisely aligned with the patterning slit sheet 151, may be formed to be relatively thick. This makes it easier to manufacture the thin film deposition assembly 100.

A plurality of thin film deposition assemblies according to FIG. 4 or FIG. 11 may be consecutively disposed in a first chamber 731 (see FIG. 1), as illustrated in FIG. 1. In this regard, each of the thin film deposition assemblies 100, 200, 300, and 400 allows different deposition materials to be deposited. In this case, patterning slits of the thin film deposition assemblies 100, 200, 300, and 400 may have different patterns, and for example, a film formation process including depositing of red, green, and blue pixels at one time may be performed.

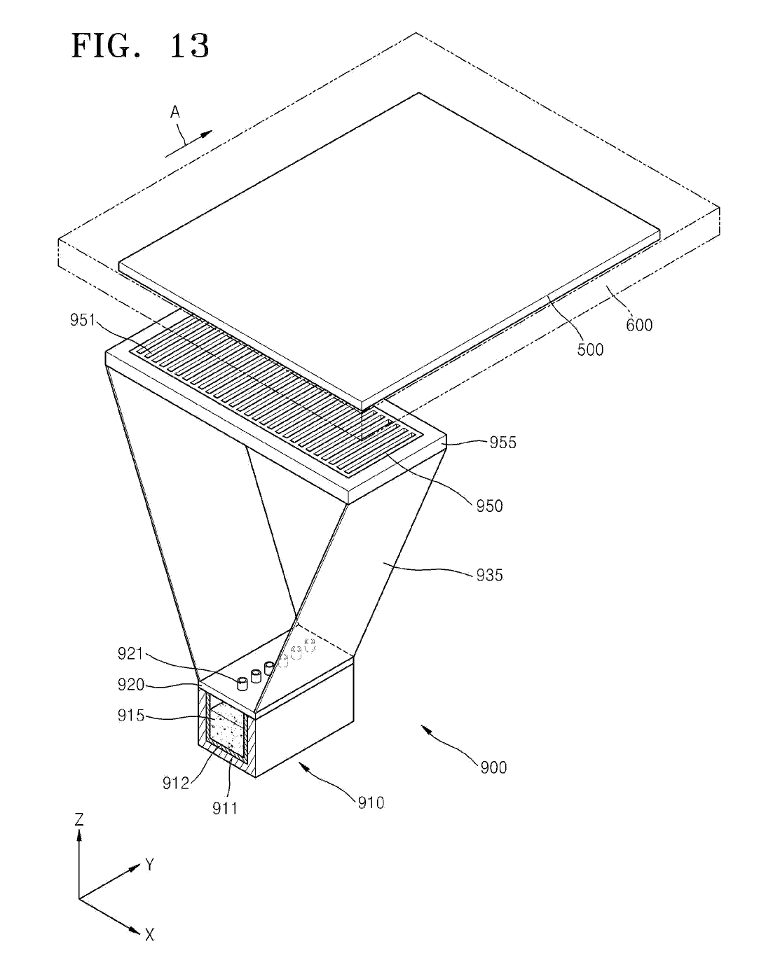

FIG. 12 is a cross-sectional view of an active matrix (AM) organic light-emitting display device manufactured by using a thin film deposition assembly, according to an embodiment of the present invention. It is to be understood that where is stated herein that one layer is “formed on” or “disposed on” a second layer, the first layer may be formed or disposed directly on the second layer or there may be intervening layers between the first layer and the second layer. Further, as used herein, the term “formed on” is used with the same meaning as “located on” or “disposed on” and is not meant to be limiting regarding any particular fabrication process.

Referring to FIG. 12, the active matrix (AM) organic light-emitting display device according to the current embodiment is disposed on a substrate 30. The substrate 30 may be formed of a transparent material, such as, for example, glass, plastic or metal. An insulating layer 31, such as a buffer layer, is formed on an entire surface of the substrate 30.

A thin film transistor (TFT) 40, a capacitor 50, and an organic light-emitting diode (OLED) 60 are disposed on the insulating layer 31, as illustrated in FIG. 12.

A semiconductor active layer 41 is formed on an upper surface of the insulating layer 31 in a predetermined pattern. A gate insulating layer 32 is formed to cover the semiconductor active layer 41. The semiconductor active layer 41 may include a p-type or n-type semiconductor material.

A gate electrode 42 of the TFT 40 is formed on an upper surface of the gate insulating layer 32 corresponding to the semiconductor active layer 41. An interlayer insulating layer 33 is formed to cover the gate electrode 42. After the interlayer insulating layer 33 is formed, the gate insulating layer 32 and the interlayer insulating layer 33 are etched by, for example, dry etching, to form a contact hole exposing parts of the semiconductor active layer 41.

Next, a source/drain electrode 43 is formed on the interlayer insulating layer 33 to contact the semiconductor active layer 41 through the contact hole. A passivation layer 34 is formed to cover the source/drain electrode 43, and is etched to expose a part of the source/drain electrode 43. A separate insulating layer (not shown) may be further formed on the passivation layer 34 so as to planarize the passivation layer 34.

In addition, the OLED 60 displays predetermined image information by emitting red, green, or blue light as according to a flow of current. The OLED 60 includes a first electrode 61 formed on the passivation layer 34. The first electrode 61 is electrically connected to the drain electrode 43 of the TFT 40.

A pixel defining layer 35 is formed to cover the first electrode 61. An opening 64 is formed in the pixel defining layer 35, and an organic layer 63 is formed in a region defined by the opening 64. A second electrode 62 is formed on the organic layer 63.

The pixel defining layer 35, which defines individual pixels, is formed of an organic material. The pixel defining layer 35 also planarizes the surface of a region of the substrate 30 where the first electrode 61 is formed, and in particular, the surface of the passivation layer 34.

The first electrode 61 and the second electrode 62 are insulated from each other, and respectively apply voltages of opposite polarities to the organic layer 63 to induce light emission.

The organic layer 63 may be formed of a low-molecular weight organic material or a polymer organic material. When a low-molecular weight organic material is used, the organic layer 63 may have a single or multi-layer structure including at least one selected from the group consisting of a hole injection layer (HIL), a hole transport layer (HTL), an emission layer (EML), an electron transport layer (ETL), an electron injection layer (ElL), etc. Examples of available organic materials may include copper phthalocyanine (CuPc), N,N′-di(naphthalene-1-yl)-N,N′-diphenyl-benzidine (NPB), tris-8-hydroxyquinoline aluminum (Alq3), etc. Such a low-molecular weight organic material may be deposited by vacuum deposition using one of the thin film deposition apparatuses or the deposition source 110 described above with reference to FIGS. 1 through 3.

After the organic layer 63 is formed, the second electrode 62 may be formed by the same deposition method as used to form the organic layer 63.

The first electrode 61 may function as an anode, and the second electrode 62 may function as a cathode. Alternatively, the first electrode 61 may function as a cathode, and the second electrode 62 may function as an anode. The first electrode 61 may be patterned to correspond to individual pixel regions, and the second electrode 62 may be formed as a common electrode to cover all the pixels.

The first electrode 61 may be formed as a transparent electrode or a reflective electrode. Such a transparent electrode may be formed of indium tin oxide (ITO), indium zinc oxide (IZO), zinc oxide (ZnO), or indium oxide (In₂O₃). Such a reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, or In₂O₃on the reflective layer. The first electrode 61 may be formed by forming a layer by, for example, sputtering, and then patterning the layer by, for example, photolithography.

The second electrode 62 may also be formed as a transparent electrode or a reflective electrode. When the second electrode 62 is formed as a transparent electrode, the second electrode 62 functions as a cathode. To this end, such a transparent electrode may be formed by depositing a metal having a low work function, such as lithium (Li), calcium (Ca), lithium fluoride/calcium (LiF/Ca), lithium fluoride/aluminum (LiF/Al), aluminum (Al), silver (Ag), magnesium (Mg), or a compound thereof on a surface of the organic layer 63 and forming an auxiliary electrode layer or a bus electrode line thereon from ITO, IZO, ZnO, In₂O₃, or the like. When the second electrode 62 is formed as a reflective electrode, the reflective layer may be formed by depositing Li, Ca, LiF/Ca, LiF/Al, Al, Ag, Mg, or a compound thereof on the entire surface of the organic layer 63. The second electrode 62 may be formed by using the same deposition method as used to form the organic layer 63 described above.

The thin film deposition assemblies according to the embodiments of the present invention described above may be applied to form an organic layer or an inorganic layer of an organic TFT, and to form layers from various materials. In particular, the thin film deposition assemblies according to the embodiments of the present invention may be used to form one or more layers of an active matrix (AM) organic light-emitting display device. It is to be understood that the active matrix (AM) organic light-emitting display device may vary from what is described above.

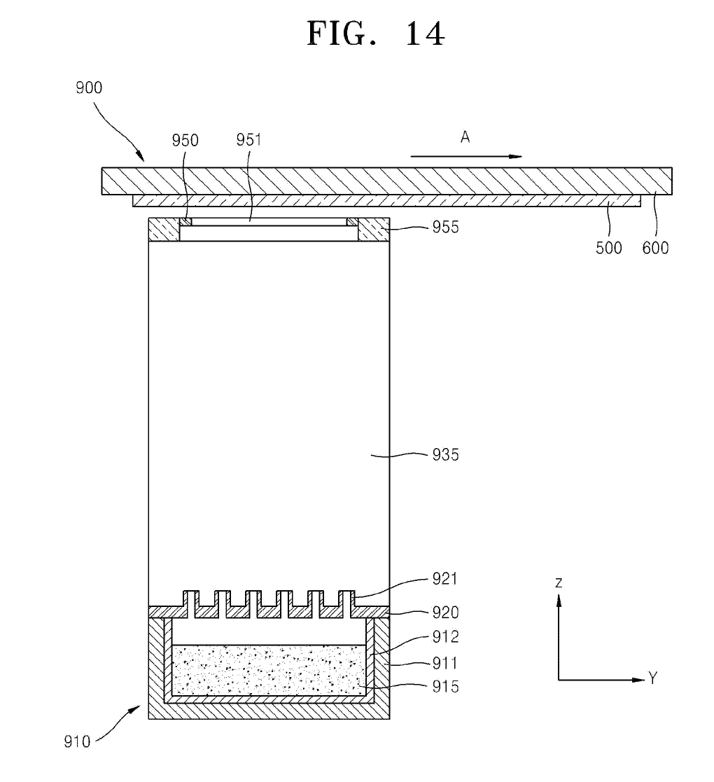

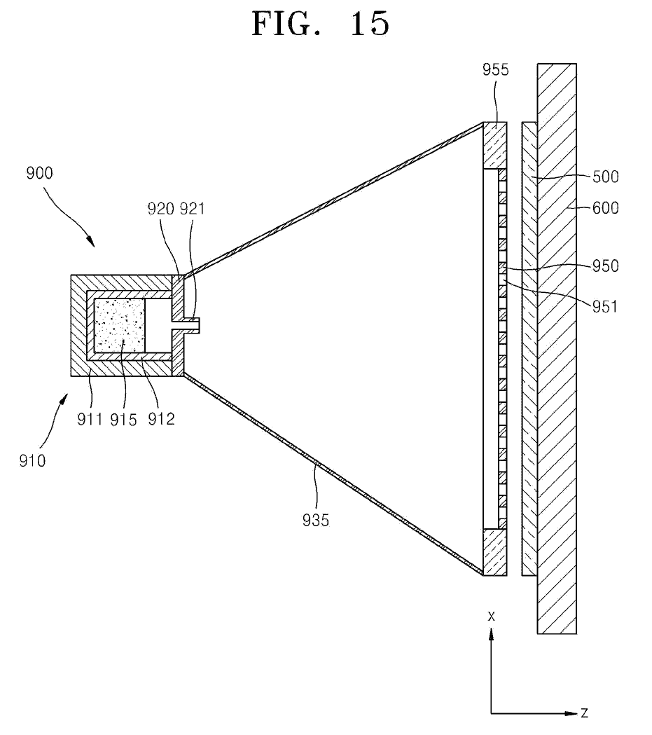

FIG. 13 is a perspective view of a thin film deposition assembly 900 according to another embodiment of the present invention, FIG. 14 is a schematic side sectional view of the thin film deposition assembly 900 illustrated in FIG. 13, according to an embodiment of the present invention, and FIG. 15 is a schematic plan sectional view of the thin film deposition assembly 900 illustrated in FIG. 13, according to an embodiment of the present invention.

Referring to FIGS. 13, 14 and 15, the thin film deposition assembly 900 according to the current embodiment includes a deposition source 910, a deposition source nozzle unit 920, and a patterning slit sheet 950.

Although a chamber is not illustrated in FIGS. 13, 14 and 15 for convenience of explanation, all the components of the thin film deposition assembly 900 may be disposed within a chamber that is maintained at an appropriate degree of vacuum. The chamber is maintained at an appropriate vacuum in order to allow a deposition material to move in a substantially straight line through the thin film deposition assembly 900.

In order to deposit a deposition material 915 emitted from the deposition source 910 and discharged through the deposition source nozzle unit 920 and the patterning slit sheet 950, onto a substrate 500 in a desired pattern, the chamber should be maintained in a high-vacuum state as in a deposition method using a fine metal mask (FMM). In addition, the temperature of the patterning slit sheet 950 should be sufficiently lower than the temperature of the deposition source 910. In this regard, the temperature of the patterning slit sheet 950 may be about 100° C. or less. The temperature of the patterning slit sheet 950 should be sufficiently low so as to reduce thermal expansion of the patterning slit sheet 950.

The substrate 500, on which the deposition material 915 is to be deposited, is disposed in the chamber. The substrate 500 may be a substrate for flat panel displays. A large substrate, such as a mother glass, for manufacturing a plurality of flat panel displays, may be used as the substrate 500. Other substrates may also be employed.

In the current embodiment of the present invention, deposition may be performed while the substrate 500 and the thin film deposition assembly 900 are moved relative to each other.

In particular, in the conventional FMM deposition method, the size of the FMM should be equal to the size of a substrate. Thus, the size of the FMM should be increased when performing deposition on a larger substrate. However, it is difficult to manufacture a large FMM and to extend an FMM to be accurately aligned with a pattern.

In order to overcome this problem, in the thin film deposition assembly 900 according to the current embodiment, deposition may be performed while the thin film deposition assembly 900 and the substrate 500 are moved relative to each other. In other words, deposition may be continuously performed while the substrate 500, which is disposed such as to face the thin film deposition assembly 900, is moved in a Y-axis direction. In other words, deposition is performed in a scanning manner while the substrate 500 is moved in a direction of arrow A in FIG. 13. Although the substrate 500 is illustrated as being moved in the Y-axis direction in FIG. 13 in the chamber when deposition is performed, aspects of the present invention are not limited thereto. Deposition may be performed while the thin film deposition assembly 900 is moved in the Y-axis direction, while the substrate 500 is fixed. For example, the transporting of the electrostatic chuck 600 having the substrate 500 fixed thereon by the first transporting unit 610 may be paused while deposition is performed.

Thus, in the thin film deposition assembly 900 according to the current embodiment, the patterning slit sheet 950 may be significantly smaller than an FMM used in a conventional deposition method. In other words, in the thin film deposition assembly 900 according to the current embodiment, deposition is continuously performed, i.e., in a scanning manner while the substrate 500 is moved in the Y-axis direction. Thus, lengths of the patterning slit sheet 950 in the X-axis and Y-axis directions may be significantly less than the lengths of the substrate 500 in the X-axis and Y-axis directions. As described above, since the patterning slit sheet 950 may be formed to be significantly smaller than an FMM used in a conventional deposition method, it is relatively easy to manufacture the patterning slit sheet 950 used in the embodiment of the present invention. In other words, using the patterning slit sheet 950, which is smaller than an

FMM used in a conventional deposition method, is more convenient in all processes, including etching and subsequent other processes, such as precise extension, welding, moving, and cleaning processes, compared to the conventional deposition method using the larger FMM. This is more advantageous for a relatively large display device.

In order to perform deposition while the thin film deposition assembly 900 and the substrate 500 are moved relative to each other as described above, the thin film deposition assembly 900 and the substrate 500 may be separated from each other by a predetermined distance. This will be described later in detail.

The deposition source 910 that contains and heats the deposition material 915 is disposed in an opposite side of the chamber to the side in which the substrate 500 is disposed. As the deposition material 915 contained in the deposition source 910 is vaporized, the deposition material 915 is deposited on the substrate 500.

The deposition source 910 includes a crucible 911 and a heater 912. The crucible 911 holds the deposition material 915. The heater 912 heats the crucible 911 to vaporize the deposition material 915 contained in the crucible 911 towards a side of the crucible 911, and in particular, towards the deposition source nozzle unit 920.

The deposition source nozzle unit 920 is disposed at a side of the deposition source 910 facing the substrate 500. The deposition source nozzle unit 920 includes a plurality of deposition source nozzles 921 arranged at equal intervals in the Y-axis direction. The deposition material 915 that is vaporized in the deposition source 910 passes through the deposition source nozzle unit 920 towards the substrate 500. As described above, when the plurality of deposition source nozzles 921 are formed on the deposition source nozzle unit 920 in the Y-axis direction, that is, the scanning direction of the substrate 500, a size of the pattern formed by the deposition material 915 that is discharged through each of patterning slits 951 in the patterning slit sheet 950 is only affected by the size of one deposition source nozzle 921, that is, it may be considered that one deposition nozzle 921 exists in the X-axis direction, and thus there is no shadow zone on the substrate 500. In addition, since the plurality of deposition source nozzles 921 are formed in the scanning direction of the substrate 500, even there is a difference between fluxes of the deposition source nozzles 921, the difference may be compensated and deposition uniformity may be maintained constantly.

The patterning slit sheet 950 and a frame 955 in which the patterning slit sheet 950 is bound are disposed between the deposition source 910 and the substrate 500. The frame 955 may be formed in a lattice shape, similar to a window frame. The patterning slit sheet 950 is bound inside the frame 955. The patterning slit sheet 950 includes a plurality of patterning slits 951 arranged in the X-axis direction. The deposition material 915 that is vaporized in the deposition source 910 passes through the deposition source nozzle unit 920 and the patterning slit sheet 950 towards the substrate 500. The patterning slit sheet 950 may be manufactured by etching, which is the same method as used in a conventional method of manufacturing an FMM, and in particular, a striped FMM. Here, the total number of patterning slits 951 may be greater than the total number of deposition source nozzles 921.

In addition, the deposition source 910, the deposition source nozzle unit 920 coupled to the deposition source 910, and the patterning slit sheet 950 may be formed to be separated from each other by a predetermined distance. Alternatively, the deposition source 910, the deposition source nozzle unit 920 coupled to the deposition source 910, and the patterning slit sheet 950 may be connected by a connection member 935. That is, the deposition source 910, the deposition source nozzle unit 920, and the patterning slit sheet 950 may be formed integrally with each other by being connected to each other via the connection member 935. The connection member 935 guides the deposition material 915, which is discharged through the deposition source nozzles 921, to move straight, and not to deviate in the X-axis direction. In FIGS. 13 through 15, the connection members 935 are formed on left and right sides of the deposition source 910, the deposition source nozzle unit 920, and the patterning slit sheet 950 to guide the deposition material 915 not to flow in the X-axis direction, however, aspects of the present invention are not limited thereto. That is, the connection member 935 may be formed as a sealed type of a box shape to guide flow of the deposition material 915 in both the X-axis and the Y-axis directions.

As described above, the thin film deposition assembly 900 according to the current embodiment performs deposition while being moved relative to the substrate 500. In order to move the thin film deposition assembly 900 relative to the substrate 500, the patterning slit sheet 950 is separated from the substrate 500 by a predetermined distance.

In particular, in a conventional deposition method using an FMM, deposition is performed with the FMM in close contact with a substrate in order to prevent formation of a shadow zone on the substrate. However, when the FMM is used in close contact with the substrate, the contact may cause defects. In addition, in the conventional deposition method, the size of the mask should be the same as the size of the substrate since the mask cannot be moved relative to the substrate. Thus, the size of the mask should be increased as display devices become larger. However, it is not easy to manufacture such a large mask.

In order to overcome this problem, in the thin film deposition assembly 900 according to the current embodiment, the patterning slit sheet 950 is disposed to be separated from the substrate 500 that is deposition target by a predetermined distance.

As described above, according to aspects of the present invention, a mask is formed to be smaller than a substrate, and deposition is performed while the mask is moved relative to the substrate. Thus, the mask can be easily manufactured. In addition, defects caused due to the contact between a substrate and an FMM, which occurs in the conventional deposition method, may be prevented. In addition, since it is unnecessary to use the FMM in close contact with the substrate during a deposition process, the manufacturing speed may be improved.

In this regard, the thin film deposition assembly 900 of FIG. 13 further includes the blocking member 800 (see FIG. 8) disposed at the edge portion of the substrate 500 fixed on the electrostatic chuck 600, thereby preventing an organic material from being deposited in an area of the substrate 500 in which no layers are to be formed. This aspect has been already described in detail with reference to FIG. 4, and thus, a detailed description thereof will not be repeated here.

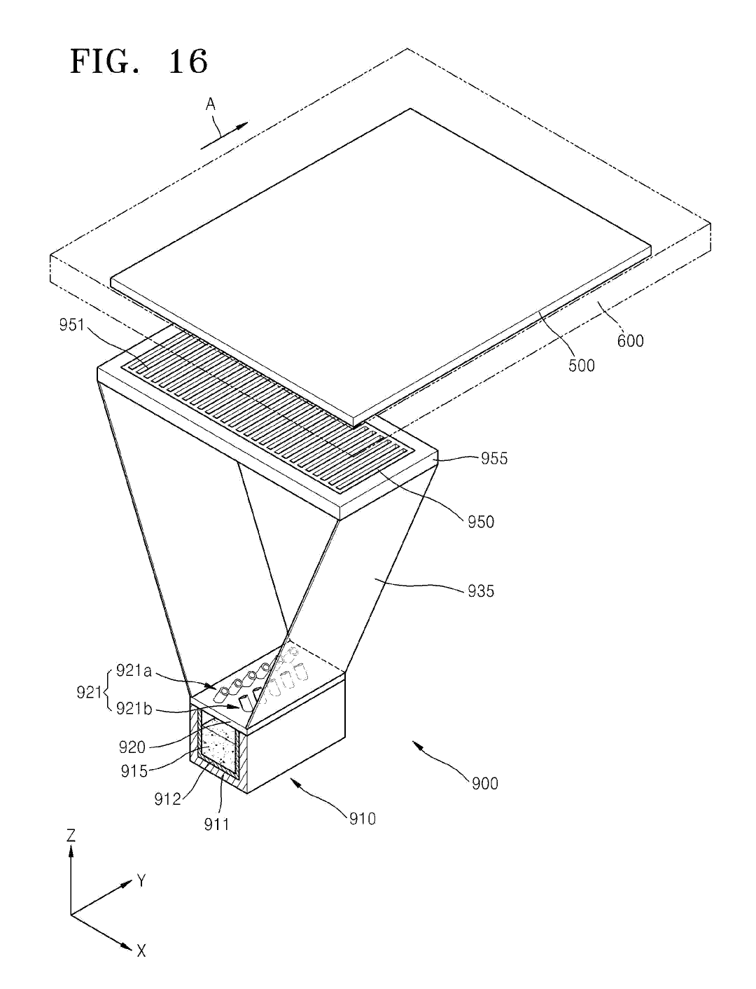

FIG. 16 is a schematic perspective view of a thin film deposition assembly 900 according to another embodiment of the present invention. Referring to FIG. 16, the thin film deposition apparatus 900 according to the current embodiment includes a deposition source 910, a deposition source nozzle unit 920, and a patterning slit sheet 950. The deposition source 910 includes a crucible 911 and a heater 912. The crucible 911 holds a deposition material 915. The heater 912 heats the crucible 911 to vaporize the deposition material 915 contained in the crucible 911 towards a side of the crucible 911, and in particular, towards the deposition source nozzle unit 920. The deposition source nozzle unit 920, which has a planar shape, is disposed at a side of the deposition source 910. The deposition source nozzle unit 920 includes a plurality of deposition source nozzles 921 arranged in the Y-axis direction. The patterning slit sheet 950 and a frame 955 are further disposed between the deposition source 910 and a substrate 500, and the patterning slit sheet 950 includes a plurality of patterning slits 951 arranged in the X-axis direction. In addition, the deposition source 910, the deposition source nozzle unit 920, and the patterning slit sheet 950 are connected to each other by a connection member 935.

In the current embodiment of the present invention, the plurality of deposition source nozzles 921 formed on the deposition source nozzle unit 920 are tilted at a predetermined angle. In particular, the deposition source nozzles 921 may include deposition source nozzles 921a and 921b which are arranged in two rows, which are alternately arranged with each other. Here, the deposition source nozzles 921a and 121b may be tilted at a predetermined angle on an X-Z plane.

Therefore, in the current embodiment of the present invention, the deposition source nozzles 921a and 921b are arranged in tilted states at a predetermined angle. For example, the deposition source nozzles 921a in a first row may be tilted at a predetermined angle toward the deposition source nozzles 921b in a second row, and the deposition source nozzles 921b in the second row may be tilted at the predetermined angle toward the deposition source nozzles 921a in the first row. That is, the deposition source nozzles 921a arranged in the row at the left side of the patterning slit sheet 950 are arranged to face the right side of the patterning slit sheet 950, and the deposition source nozzles 921b arranged in the row at the right side of the patterning slit sheet 150 are arranged to face the left side of the patterning slit sheet 950.

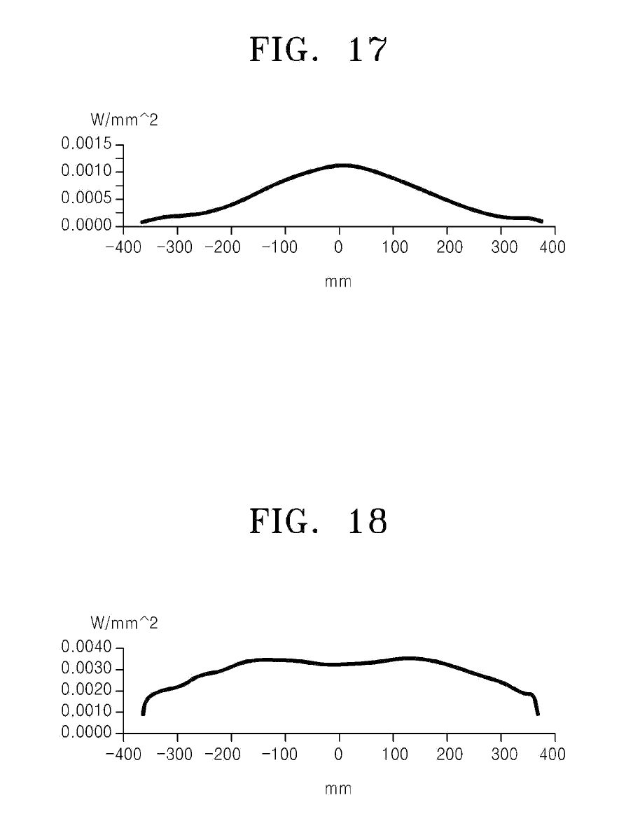

FIG. 17 is a graph schematically illustrating a distribution pattern of a deposition layer formed on a substrate when a deposition source nozzle is not tilted, in the thin film deposition assembly 900 of FIG. 16, according to an embodiment of the present invention, and FIG. 18 is a graph showing a distribution of the deposition layer formed on the substrate when the deposition source nozzles are tilted, in the thin film deposition assembly 900 of FIG. 16, according to the current embodiment of the present invention. Comparing the graphs of FIGS. 17 and 18 with each other, a thickness of the deposition layer formed on both end portions of the substrate when the deposition source nozzles are tilted is relatively greater than that of the deposition layer formed on the substrate when the deposition source nozzles are not tilted, and thus, the uniformity of the deposition layer is improved.

Therefore, the deposition amount of the deposition material may be adjusted so that a difference between the thicknesses of the deposition layer at the center portion and end portions of the substrate may be reduced and the entire thickness of the deposition layer may be constant, and moreover, the efficiency of utilizing the deposition material may be improved.

In this regard, the thin film deposition assembly 900 of FIG. 16 further includes the blocking member 800 (see FIG. 8) disposed at the edge portion of the substrate 500 fixed on the electrostatic chuck 600, thereby preventing an organic material from being deposited in an area of the substrate 500 in which no layers are to be formed. This aspect has been already described in detail with reference to FIG. 4, and thus, a detailed description thereof will not be repeated here.

As described above, in a thin film deposition apparatus according to aspects of the present invention and a method of manufacturing an organic light-emitting display device according to aspects of the present invention by using the thin film deposition apparatus, the thin film deposition apparatus may be simply applied to manufacture large-sized display devices on a mass scale. In addition, the thin film deposition apparatus and the organic-light-emitting display device may be easily manufactured, may improve manufacturing yield and deposition efficiency, and may allow deposition materials to be reused.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thin film deposition apparatus comprising:
an electrostatic chuck that fixes a substrate on which a deposition material is to be deposited;
a blocking member that is disposed at a side of the substrate fixed on the electrostatic chuck and that covers at least a portion of the substrate; and
a deposition unit comprising a chamber and at least one thin film deposition assembly disposed in the chamber to deposit a thin film on the substrate fixed on the electrostatic chuck.

2. The thin film deposition apparatus of claim 1, wherein the blocking member covers an area of the substrate in which no layers are to be formed.

3. The thin film deposition apparatus of claim 1, wherein the blocking member covers a border portion of the substrate.

4. The thin film deposition apparatus of claim 1, wherein at least a portion of the substrate is interposed between the electrostatic chuck and the blocking member.

5. The thin film deposition apparatus of claim 1, wherein the blocking member comprises a frame including an open area and a blocking sheet attached to a side of the frame and covering at least a portion of the substrate.

6. The thin film deposition apparatus of claim 1, further comprising a magnet and a magnetic substance disposed so that the blocking member is fixed on the electrostatic chuck due to a magnetic force between the magnet and the magnetic substance, wherein the magnet is disposed at the electrostatic chuck and the magnetic substance is disposed at the blocking member, or the magnet substance is disposed at the electrostatic chuck and the magnet is disposed at the blocking member.

7. The thin film deposition apparatus of claim 1, further comprising:
a loading unit that fixes the substrate on which a deposition material is to be deposited onto the electrostatic chuck;
an unloading unit that separates the substrate on which deposition has been performed from the electrostatic chuck;
a first circulation unit that sequentially moves the electrostatic chuck on which the substrate is fixed to the loading unit, from the loading unit to the deposition unit, and from the deposition unit to the unloading unit; and
a second circulation unit that returns the electrostatic chuck, after the electrostatic chuck has been separated from the substrate by the unloading unit, to the loading unit,
wherein the first circulation unit is disposed to pass through the chamber while traversing the deposition unit.

8. The thin film deposition apparatus of claim 7, wherein more than one thin film deposition assembly is disposed in the chamber.

9. The thin film deposition apparatus of claim 7, wherein the chamber comprises a first chamber and a second chamber, wherein each of the first chamber and the second chamber has at least one thin film deposition assembly disposed therein, and wherein the first chamber and the second chamber are connected to each other.

10. The thin film deposition apparatus of claim 1, wherein the at least one thin film deposition assembly comprises:
a deposition source that discharges a deposition material;
a deposition source nozzle unit disposed at a side of the deposition source and including a plurality of deposition source nozzles arranged in a first direction;
a patterning slit sheet disposed opposite to and spaced apart from the deposition source nozzle unit and including a plurality of patterning slits arranged in the first direction; and
a barrier wall assembly disposed between the deposition source nozzle unit and the patterning slit sheet, and including a plurality of barrier walls in the first direction that partition a space between the deposition source nozzle unit and the patterning slit sheet into a plurality of sub-deposition spaces, and
wherein the thin film deposition assembly is spaced apart from the substrate, and
the thin film deposition assembly and the substrate are movable relative to each other.

11. The thin film deposition apparatus of claim 10, wherein the patterning slit sheet of the thin film deposition assembly is smaller than the substrate.

12. The thin film deposition apparatus of claim 10, wherein each of the plurality of barrier walls extends in a second direction substantially perpendicular to the first direction.

13. The thin film deposition apparatus of claim 10, wherein the plurality of barrier walls are arranged at equal intervals.

14. The thin film deposition apparatus of claim 10, wherein the barrier wall assembly comprises a first barrier wall assembly comprising a plurality of first barrier walls, and a second barrier wall assembly comprising a plurality of second barrier walls.

15. The thin film deposition apparatus of claim 14, wherein each of the first barrier walls and each of the second barrier walls extend in a second direction substantially perpendicular to the first direction.

16. The thin film deposition apparatus of claim 15, wherein the first barrier walls are arranged to respectively correspond to the second barrier walls.

17. The thin film deposition apparatus of claim 16, wherein each pair of the corresponding first and second barrier walls is arranged on substantially the same plane.

18. The thin film deposition apparatus of claim 10, wherein the deposition source and the barrier wall assembly are spaced apart from each other.

19. The thin film deposition apparatus of claim 10, wherein the barrier wall assembly is spaced apart from the patterning slit sheet.

20. The thin film deposition apparatus of claim 10, wherein the chamber includes a plurality of the thin film deposition assemblies and wherein the deposition materials contained in the deposition sources of the plurality of thin film deposition assemblies are continuously deposited on the substrate while the substrate and/or the thin film deposition assembly are moved relative to each other.

21. The thin film deposition apparatus of claim 10, wherein the thin film deposition assembly andr the substrate are movable relative to each other along a plane parallel to a surface of the substrate on which the deposition materials are deposited.

22. The thin film deposition apparatus of claim 7, wherein the thin film deposition assembly comprises:
a deposition source that discharges a deposition material;
a deposition source nozzle unit disposed at a side of the deposition source and including a plurality of deposition source nozzles arranged in a first direction; and
a patterning slit sheet disposed opposite to the deposition source nozzle unit and including a plurality of patterning slits arranged in a second direction perpendicular to the first direction, and
wherein deposition is performed while the substrate and the thin film deposition assembly are moved relative to each other in the first direction, and
wherein the deposition source, the deposition source nozzle unit, and the patterning slit sheet are formed integrally with each other.

23. The thin film deposition apparatus of claim 22, wherein the deposition source and the deposition source nozzle unit, and the patterning slit sheet are connected to each other by a connection member.

24. The thin film deposition apparatus of claim 23, wherein the connection member guides movement of the discharged deposition material.

25. The thin film deposition apparatus of claim 22, wherein the plurality of deposition source nozzles comprise deposition source nozzles arranged in two rows disposed in the first direction, and wherein each of the deposition source nozzles in each of the two rows is tilted at a predetermined angle toward a corresponding deposition source nozzle of the other of the two rows.

26. The thin film deposition apparatus of claim 22, wherein the plurality of deposition source nozzles comprise deposition source nozzles arranged in two rows disposed in the first direction, and
the deposition source nozzles arranged in a row located at a first side of the patterning slit sheet are arranged to face a second side of the patterning slit sheet, and
the deposition source nozzles arranged in the other row located at the second side of the patterning slit sheet are arranged to face the first side of the patterning slit sheet.

27. A method of manufacturing an organic light-emitting display device, the method comprising:
fixing a substrate on an electrostatic chuck;
disposing a blocking member at a side of the substrate fixed on the electrostatic chuck to cover at least a portion of the substrate; and
depositing a thin film on the substrate fixed on the electrostatic chuck.

28. The method of claim 27, wherein the disposing of the blocking member at a side of the substrate fixed on the electrostatic chuck to cover at least a portion of the substrate comprises disposing the blocking member to cover an area of the substrate in which no layers are to be formed.

29. The method of claim 27, wherein the disposing of the blocking member at a side of the substrate fixed on the electrostatic chuck to cover at least a portion of the substrate comprises disposing the blocking member to cover a border portion of the substrate.

30. The method of claim 27, wherein the depositing of the thin film on the substrate fixed on the electrostatic chuck comprises:
conveying the electrostatic chuck on which the substrate is fixed from a loading location to a chamber by engaging the electrostatic chuck with a first circulation unit that passes through the chamber;
moving the substrate and a thin film deposition assembly disposed in the chamber relative to each other such that a deposition material discharged from the thin film deposition assembly is deposited on the substrate;
engaging the first circulation unit to remove the substrate on which deposition has been performed from the chamber;
separating the substrate on which deposition has been performed from the electrostatic chuck; and
engaging the electrostatic chuck separated from the substrate with a second circulation unit installed outside the chamber to return the electrostatic chuck to the loading location.

31. The method of claim 30, wherein a plurality of thin film deposition assemblies are disposed in the chamber, and wherein deposition is continuously performed on the substrate by using each of the plurality of thin film deposition assemblies.

32. The method of claim 30, wherein the chamber comprises a first chamber and a second chamber, wherein the first chamber and the second chamber each include a plurality of thin film deposition assemblies, wherein the first chamber and the second chamber are connected to each other, and wherein deposition is continuously performed while the substrate is moved through the first chamber and the second chamber.

33. The method of claim 30, wherein the thin film deposition assembly comprises:
a deposition source that discharges the deposition material;
a deposition source nozzle unit disposed at a side of the deposition source and including a plurality of deposition source nozzles arranged in a first direction;
a patterning slit sheet disposed opposite to and spaced apart from the deposition source nozzle unit and including a plurality of patterning slits arranged in the first direction; and
a barrier wall assembly disposed between the deposition source nozzle unit and the patterning slit sheet in the first direction, and including a plurality of barrier walls that partition a space between the deposition source nozzle unit and the patterning slit sheet into a plurality of sub-deposition spaces, and
wherein the thin film deposition assembly is spaced apart from the substrate, and
wherein depositing of the thin film on the substrate is performed while the thin film deposition assembly and the substrate are moved relative to each other.

34. The method of claim 30, wherein the thin film deposition assembly comprises:
a deposition source that discharges the deposition material;
a deposition source nozzle unit disposed at a side of the deposition source and including a plurality of deposition source nozzles arranged in a first direction; and
a patterning slit sheet disposed opposite to and spaced apart from the deposition source nozzle unit and including a plurality of patterning slits arranged in a second direction perpendicular to the first direction, and
wherein depositing of the thin film on the substrate is performed while the substrate and the thin film deposition assembly are moved relative to each other in the first direction, and
wherein the deposition source, the deposition source nozzle unit, and the patterning slit sheet are formed integrally with each other.
